(19) United States
(12) Patent Application Publication
(10) Pub. No.: US 2024/0128203 A1
(43) Pub. Date: Apr. 18, 2024

(54) CHIP SIZE PACKAGE AND SYSTEM

(71) Applicant: STMicroelectronics PTE LTD, Singapore (SG)

(72) Inventor: Jing-En LUAN, Singapore (SG)

(73) Assignee: STMicroelectronics PTE LTD, Singapore (SG)

(21) Appl. No.: 18/369,441

(22) Filed: Sep. 18, 2023

Related U.S. Application Data
(60) Provisional application No. 63/417,099, filed on Oct. 18, 2022.

(51) Int. Cl. H01L 23/00; H01L 21/3065; H01L 21/768; H01L 21/78; H01L 23/36; H01L 23/48

(52) U.S. Cl. CPC H01L 23/562; H01L 21/3065; H01L 21/76898; H01L 21/78; H01L 23/36; H01L 23/481; H01L 24/03; H01L 24/16; H01L 2224/0346; H01L 2224/16145; H01L 2224/16227

(57) ABSTRACT

A method of manufacturing a chip-sized package includes providing a wafer having a die area formed therein adjacent a front face thereof, with the die area having pads formed thereon. Vias in the wafer are formed to extend between a back face of the wafer and a back side of some of the pads of the die area. Solder pads connected to the vias are formed, and a thermal pad is formed on the back side of the wafer opposite to the die area. Cavities are formed in the back face of the wafer to define pillars extending outwardly from a planar portion of the die area, some of the pillars having the solder pads at a distal end thereof, at least one of the pillars having the thermal pad at a distal end thereof. The wafer is singulated to form a chip-sized package including an integrated circuit die.

### RELATED APPLICATION

This application claims priority to U.S. Provisional Application Patent No. 63/417,099, filed Oct. 18, 2022, the contents of which are incorporated by reference in their entirety.

### TECHNICAL FIELD

This disclosure is related to the field of packaging and, in particular, to techniques for manufacturing chip sized packages which provide for increased reliability through the use of pillars to connect the packages to printed circuit boards.

### BACKGROUND

Integrated circuits are formed on wafers of semiconductor material. On a typical semiconductor wafer, many identical integrated circuits are formed. The wafer is then diced or cut into many dice, each die including an integrated circuit. The die is then packaged both to protect it from physical damage and to place it in a form which can be easily installed in a system of which it will be a part.

A sample integrated circuit package 10 is now described with reference to FIG. 1 and is formed in a wafer-level chip-sized package arrangement. The integrated circuit package 10 includes a die 11 that has bonding pads 12 formed on its front face, with its back face left exposed. A passivation layer 13 is formed on the front face of the die 11, with holes formed in the passivation layer 13 to expose the bonding pads 12. A first polyimide layer 14 is formed on the passivation layer 13, with holes being formed in the first polyimide layer 14 aligned with the holes in passivation layer 13 to expose the bonding pads 12 such that a redistribution layer 15 formed on the first polyimide layer 14 extends therethrough to contact the bonding pads 12. A second polyimide layer 16 is formed over the redistribution layer 15 and first polyimide layer 14, with holes formed in the second polyimide layer 16 to permit solder balls 17 to make contact with the redistribution layer 15.

This integrated circuit package 10 is suitable for use in systems and products. For example, the integrated circuit package 10 may be mounted to a printed circuit board via its solder balls 17 for use in a flip-chip arrangement. While this design is sufficient for use in some applications, and indeed is used in many products, the solder balls 17 consume an undesirable amount of area (preventing such packages from having pitches as low as desired in some instances) and their rigidity (and the overall rigidity of the package) introduces a potential point of failure due to mechanical stresses. As such, further development is needed.

### SUMMARY

Disclosed herein is a method of manufacturing at least a chip-sized package. The method includes providing a wafer having a die area formed therein adjacent a front face thereof, the die area having pads formed thereon. The method continues with forming vias in the wafer extending between a back face of the wafer and a back side of some of the pads of the die area and forming solder pads connected to the vias and forming a thermal pad on the back side of the wafer opposite to the die area. The method then proceeds to forming cavities in the back face of the wafer to define pillars extending outwardly from a planar portion of the die area, some of the pillars having the solder pads at a distal end thereof, at least one of the pillars having the thermal pad at a distal end thereof. Thereafter, the method concludes with singulating the wafer to form a chip-sized package including an integrated circuit die, the integrated circuit die formed from remains of the die area after singulation.

Vias may be formed in the wafer by forming holes in the wafer extending between the back face of the wafer and the back side of some of the pads of the die area, and plating the holes to form through silicon vias.

The solder pads and the thermal pad on the back face of the wafer opposite to the die area may be formed by plating the back face of the wafer opposite to the die area and performing etching to form the solder pads and the thermal pad.

The cavities may be formed in the back face of the wafer by plasma etching the back face of the wafer.

The method may also include attaching the integrated circuit die to a printed circuit board by soldering the pads on the front face of the integrated circuit die to pads on a top face of the printed circuit board.

The method may also include, prior to forming the vias in the wafer, providing a secondary integrated circuit having pads on a front face thereof and attaching the secondary integrated circuit to the die area by connecting some of the pads of the die area to the pads of the secondary integrated circuit via solder balls.

The method may also include, after attaching the secondary integrated circuit to the die area but prior to forming the vias in the wafer, forming a molding layer over the front face of the wafer and portions of the secondary integrated circuit.

The method may include placing the wafer with its front face down on a carrier prior to forming the vias.

Also disclosed herein is a method of increasing board level reliability of a system including a chip-sized package mounted to a printed circuit board. This method includes forming cavities in a back face of a primary integrated circuit die within the chip-sized package to define pillars extending outwardly from a planar portion of the primary integrated circuit die, forming pads on distal ends of the pillars, and soldering those pads to corresponding pads on the printed circuit board.

This method may also include attaching a secondary integrated circuit die to a front face of the primary integrated circuit die by connecting pads on the front face of the primary integrated circuit die to pads of the secondary integrated circuit via solder balls.

Also included is a system including a chip-sized package mounted to a printed circuit board. The chip-sized package includes a primary integrated circuit die having its back face connected to a printed circuit board, cavities formed in a back face of the primary integrated circuit die to define pillars extending outwardly from a planar portion of the primary integrated circuit die, and pads formed on distal ends of the pillars, wherein the pads on the distal ends of the pillars are connected to corresponding pads on the printed circuit board by surface mount solder.

The chip-sized package may include a secondary integrated circuit die mounted to a front face of the primary integrated circuit die via solder balls between corresponding pads of the secondary integrated circuit die and the primary integrated circuit die.

The primary integrated circuit die may have through-silicon vias extending from a back face of pads formed in a front face of the primary integrated circuit die to corresponding ones of the pads on the distal end of the pillars.

One of the pillars defined by the cavities may have a thermal pad on its distal end, and the thermal pad may be connected to a corresponding pad on the printed circuit board by surface mount solder.

The primary integrated circuit die may have through-silicon vias extending from a back face of pads formed in a front face of the primary integrated circuit die to corresponding ones of the pads on the distal end of the pillars. One of the pillars defined by the cavities may have a thermal pad on its distal end, with this pillar lacking a through-silicon via extending therethrough. The thermal pad may be connected to a corresponding pad on the printed circuit board by surface mount solder.

### BRIEF DESCRIPTION OF THE DRAWINGS

FIG. 1 is a cross sectional view of a prior art chip sized package.

FIG. 2 is a cross sectional view of a chip sized package such as may be formed using a process flow described herein, as installed on a printed circuit board.

FIG. 3 is a cross sectional view showing the chip sized package at a first step in which the wafer is provided.

FIG. 4 is a cross sectional view showing the chip sized package at a second step in which secondary chips are mounted adjacent to die areas on the wafer.

FIG. 5 is a cross sectional view showing the chip sized package of FIG. 4 after deposition of moulding material.

FIG. 6 is a cross sectional view showing the chip sized package of FIG. 5 as flipped and placed on a carrier.

FIG. 7 is a cross sectional view showing the chip sized package of FIG. 6 after formation of through-silicon vias therein.

FIG. 8 is a cross sectional view showing the chip sized package of FIG. 7 after plating of the vias.

FIG. 9 is a cross sectional view showing the chip sized package of FIG. 8 after an etching step.

FIG. 10 is a cross sectional view showing the chip sized package of FIG. 9 after plasma etching and singulation.

FIG. 11 is a cross sectional view showing the chip sized package of FIG. 10 after removal from the carrier.

FIG. 12 is a cross sectional view showing another chip sized package under formation at a first step in which the wafer is provided.

FIG. 13 is a cross sectional view showing the chip sized package of FIG. 12 after mounting on a carrier and formation of through-silicon vias therein.

FIG. 14 is a cross sectional view showing the chip sized package of FIG. 13 after plating of the vias.

FIG. 15 is a cross sectional view showing the chip sized package of FIG. 14 after an etching step.

FIG. 16 is a cross sectional view showing the chip sized package of FIG. 16 after plasma etching and singulation.

FIG. 17 is a cross sectional view showing the chip sized package of FIG. 16 after removal from the carrier.

FIG. 18 is a bottom view of the chip sized package of FIG. 17.

### DETAILED DESCRIPTION

The following disclosure enables a person skilled in the art to make and use the subject matter disclosed herein. The general principles described herein may be applied to embodiments and applications other than those detailed above without departing from the spirit and scope of this disclosure. This disclosure is not intended to be limited to the embodiments shown but is to be accorded the widest scope consistent with the principles and features disclosed or suggested herein.

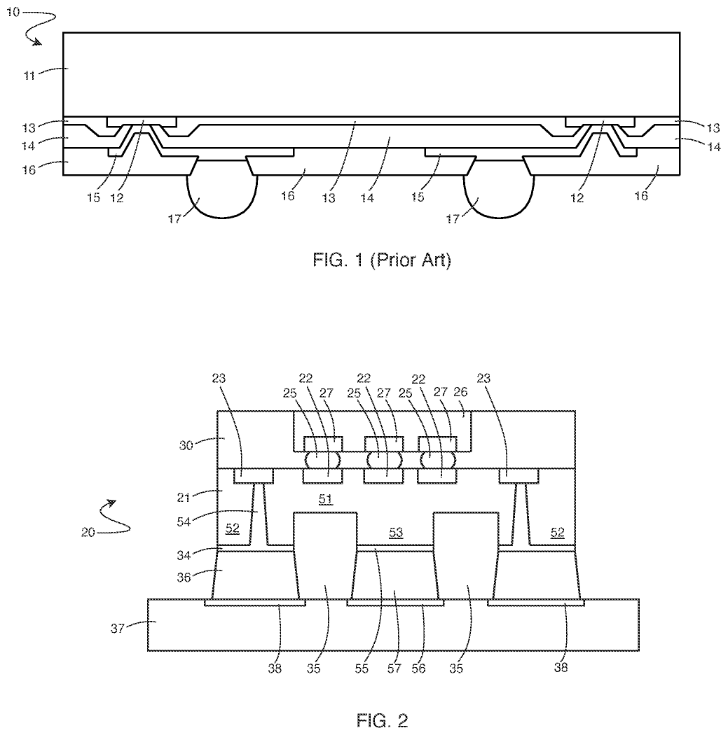

First, a chip size package 20 disclosed herein will be described with reference to FIG. 2, and thereafter, the manufacturing process for the chip size package 20 will be described. The chip sized package 20 includes a primary silicon die 21 that is formed to have a planar portion 51 with an active area formed therein, with pillars 52, 53 extending therefrom. The pillar 53 may be centrally located within the planar portion 51. Pads 22, 23 are formed on the front face of the primary die 21, with pads 23 overlying the pillars 52, and with pads 22 overlying the planar portion 51. Vias 54 extend through the pillars 52 to electrically connect the pads 23 to pads 34 formed on the distal ends of the pillars 52. A thermal pad 55 is formed on the back face of the primary die 21 on the distal end of the pillar 53.

Solder joints 36 electrically and mechanically connect the primary die 21 (and therefore the package 20) to pads 38 on the front face of a printed circuit board (PCB) 37. In particular, the pads 34 of the primary die 21 are electrically and mechanically connected to pads 38 of the PCB 37 by the solder joints 36, and the thermal pad 55 is mechanically connected to pad 56 of the PCB 37 by solder joint 57.

Solder balls 25 connect the pads 22 of the primary die 21 to pads 27 of a secondary die 26. A moulding compound 30 environmentally seals the top face of the primary die 21 and sides and front face of the secondary die 26, with the back face of the secondary die 26 being left exposed.

The shape of the back face of the primary die 21 (e.g., the planar portion 51 with pillars 52, 53 extending therefrom) forms open chambers 35 with the front face of the PCB 37. This arrangement provides for the ability of the primary die 21 to flex as the PCB 37 flexes, and/or as the mismatch in thermal coefficients of expansion between the primary die 21 and PCB 37 imparts mechanical stresses on the primary die 21. This ability to flex effectively mechanically decouples the secondary die 26 from these mechanical stresses, so that the mechanical connection between the primary die 21 and secondary die 26 does not transmit mechanical stresses to the secondary die 26 that were imparted onto the primary die 21 due to its mechanical connection with the PCB 37. This increases and enhances board level reliability over prior art designs, extending the thermal cycling life of the formed package 20. In addition, this protection against mechanical stresses allows for the secondary die 26 to be a smaller device, a thinner device, or a more fragile device than could be used in prior art designs—fewer mechanical stresses are placed on the active area of the secondary die 26 and the active area of the primary die 21. Furthermore, the use of the solder pads 34 to connect the primary die 21 to the PCB 37 allows for the creation of packages with a finer pitch than would be possible using the solder balls of conventional techniques.

As examples of specific applications, the primary die 21 may be an ASIC and the secondary die 26 may be a microelectromechanical system (MEMS) device.

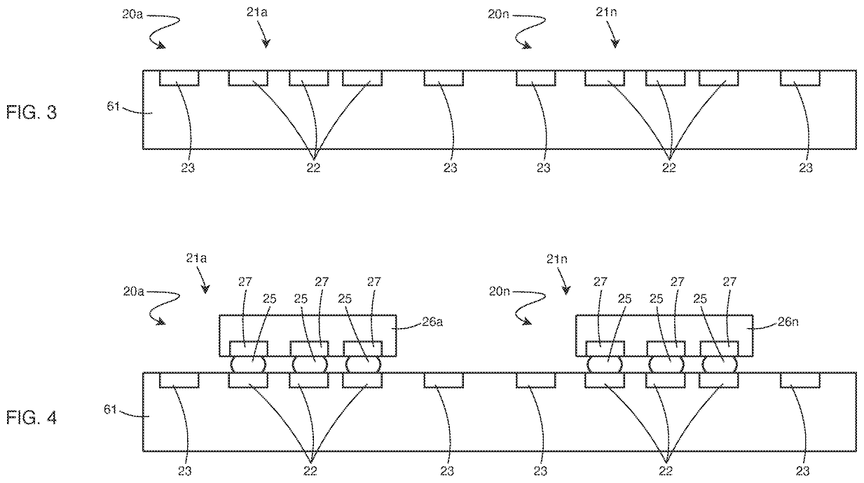

A process flow for manufacturing the package 20 is now described with additional reference to FIGS. 3-12. The process flow begins with the provision of an incoming silicon wafer 61, as shown in FIG. 3. The incoming wafer 61 will ultimately form integrated circuit die 21a, . . . , 21n (with n being any integer number); at this stage the references 21a, . . . , 21n will be described as die areas. Each die area 21a, . . . , 21n has an active area formed therein adjacent the front face of the wafer 61, with pads 22 on the front faces thereof being electrically connected to the active areas. Each die area 21a, . . . , 21n also has pads 23 on its front face being electrically connected to its active area.

Next, as shown in FIG. 4, secondary die 26a, . . . , 26n are electrically and mechanically connected to the pads 22 of the die areas 21a, . . . , 21n through solder balls 25. Therefore, each die area 21a, . . . , 21n has a secondary die 26a, . . . , 26n mounted thereto.

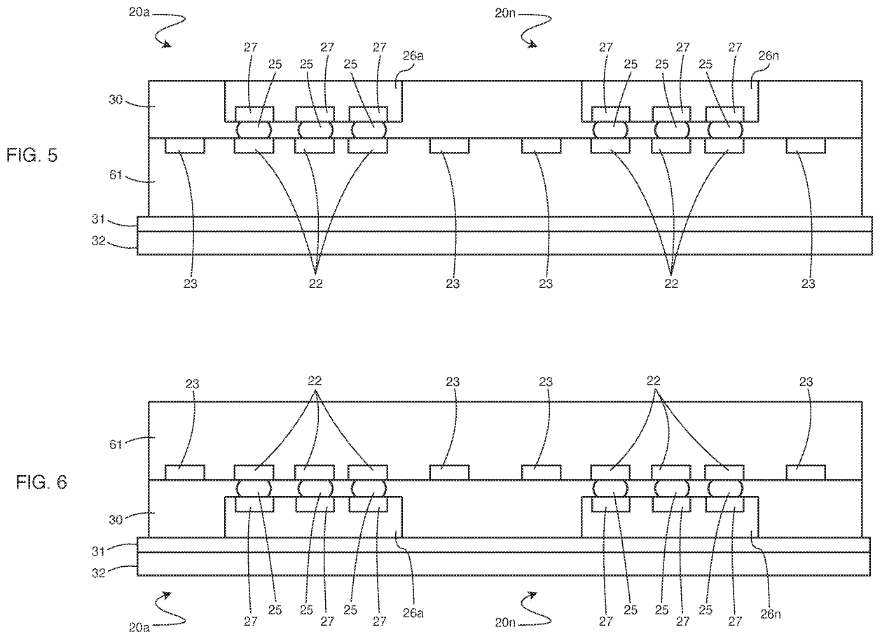

Thereafter, the wafer 61 is placed on a layer of tape 31 stacked on a carrier 32, and resin 30 is deposited over the wafer 61, cured, and ground down such that the back faces of the secondary die 26a, . . . , 26n are left exposed, as shown in FIG. 5. The wafer 61 is then flipped, so that the back faces of the secondary die 26a, . . . , 26n and the resin layer 30 are stacked on a new piece of tape 31 on a different carrier 32 as shown in FIG. 6.

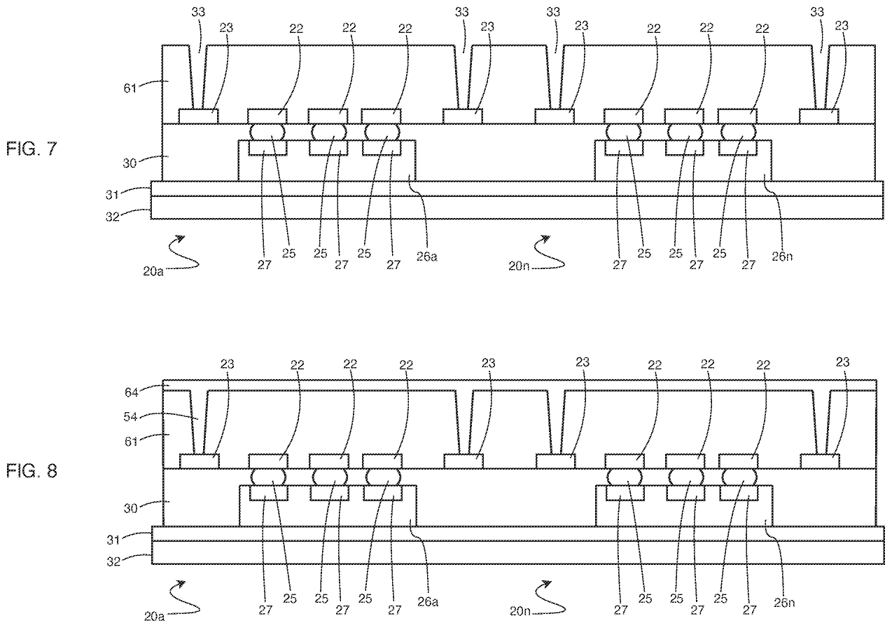

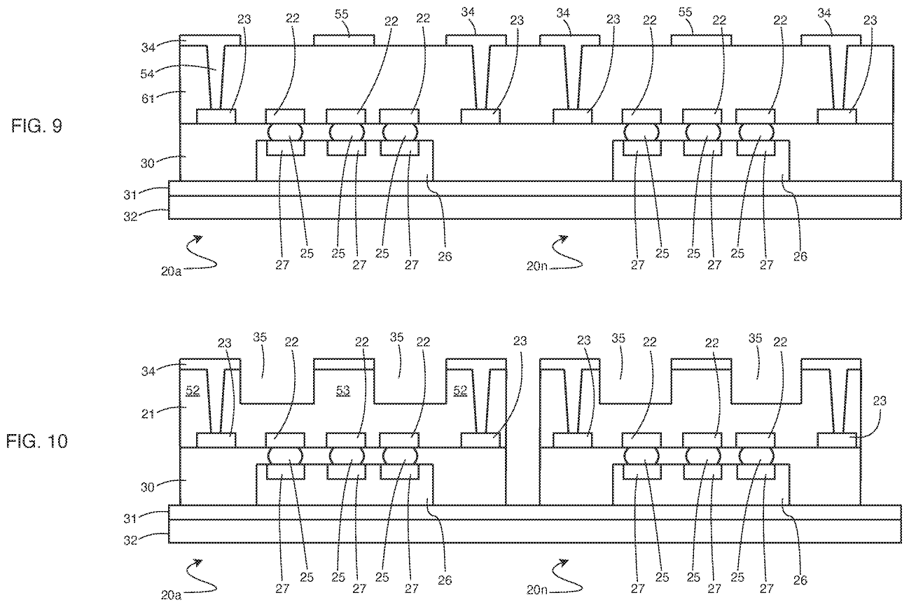

The back face of the wafer 61 may then be thinned if desired and holes 33 for through-silicon vias are then formed in the back face of the wafer 61 in alignment with the pads 23, as shown in FIG. 7. Plating is performed to form a metal layer 64 stacked on the back face of the wafer 61. The metal layer 64 extends through the holes 33 to form through silicon vias 54, as shown in FIG. 8. The metal layer 64 is etched to form individual pads 34 connected to the through silicon vias 54, and thermal pads 55 spaced apart therefrom, as shown in FIG. 9.

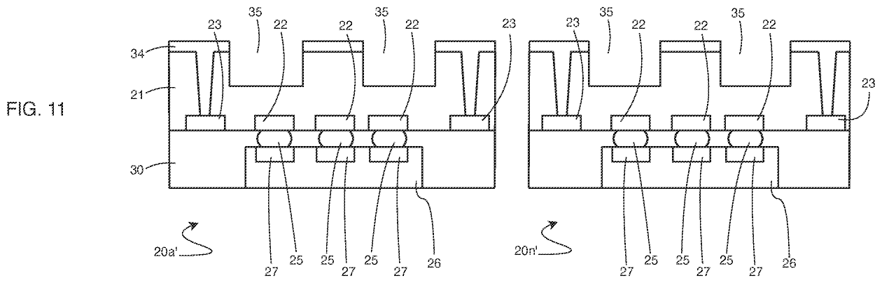

Cavities 35 are then formed in the back face of the wafer 61, thereby defining pillars 52, 53, as shown in FIG. 10. The cavities 35 extend laterally between adjacent ones of the pads 34 and thermal pads 55, and extend partway into (but not fully through) the thickness of the wafer 61 such that the portions of wafer material between the surface of the cavities 34 and the pads 22 that contain the active areas remain unharmed. Singulation is then performed via plasma etching or dicing, forming the separate packages 20a, . . . , 20n. The packages 20a, . . . , 20n are then removed from the tape 31 and carrier 32, as shown in FIG. 11.

The packages 20a, . . . , 20n are thereafter flipped and mechanically and electrically connected to the PCB 37. Solder joints 36 are formed to electrically and mechanically connect the die 21 to pads 38 on the front face of the PCB 37 via surface mount soldering and the thermal pad 55 is mechanically connected to pad 56 of the PCB 37 by solder joint 57 via surface mount soldering. This produces the package of FIG. 2.

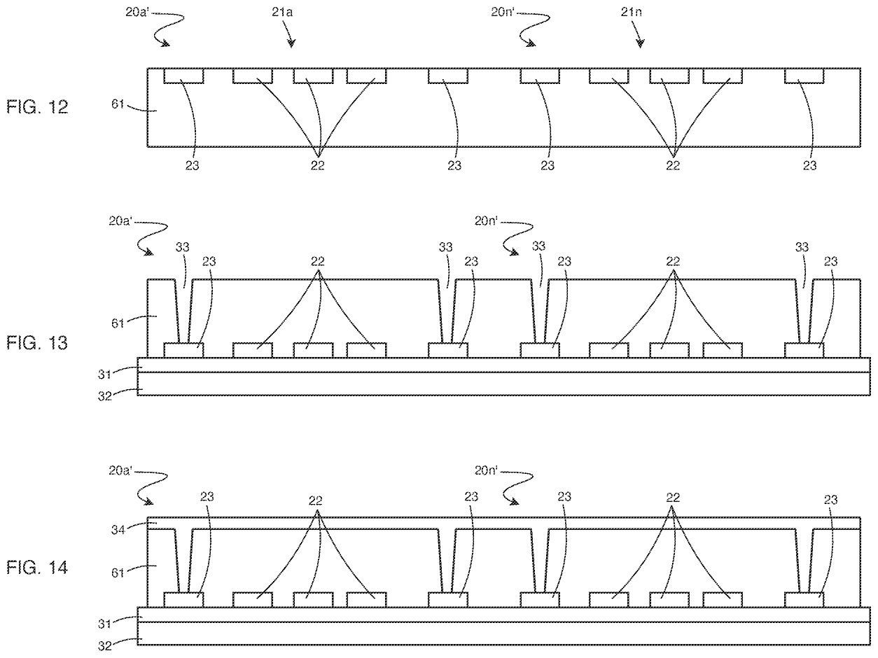

Now described with reference to FIGS. 12-18 is a process flow for manufacturing an alternative embodiment of the package 20′ in which the secondary die 26 are not present. The process flow begins with the provision of an incoming silicon wafer 61, as shown in FIG. 12. The incoming wafer 61 will ultimately form integrated circuit die 21a, . . . , 21n (with n being any number); the references 21a, . . . , 21n will be described hereinafter as die areas. Each die area 21a, . . . , 21n has an active area formed therein adjacent the front face of the wafer 61, with pads 22 on the front faces thereof being electrically connected to the active areas. Each die area 21a, . . . , 21n also has pads 23 on its front face being electrically connected to its active area.

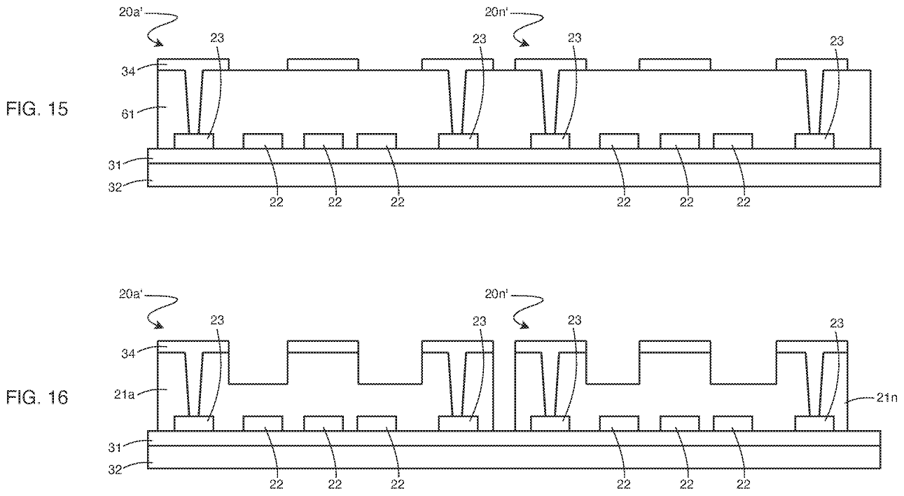

Thereafter, the wafer 61 is flipped and placed on a layer of tape 31 stacked on a carrier 32 such that the front face of the wafer 61 is on the tape 31, as shown in FIG. 13. The back face of the wafer 61 may then be thinned if desired and holes 33 for through-silicon vias are then formed in the back face of the wafer 61 in alignment with the pads 23, as shown in FIG. 13. Plating is performed to form a metal layer 64 stacked on the back face of the wafer 61. The metal layer 64 extends through the holes 33 to form through silicon vias 54, as shown in FIG. 14. The metal layer 64 is etched to form individual pads 34 connected to the through silicon vias 54, and thermal pads 55 spaced apart therefrom, as shown in FIG. 15.

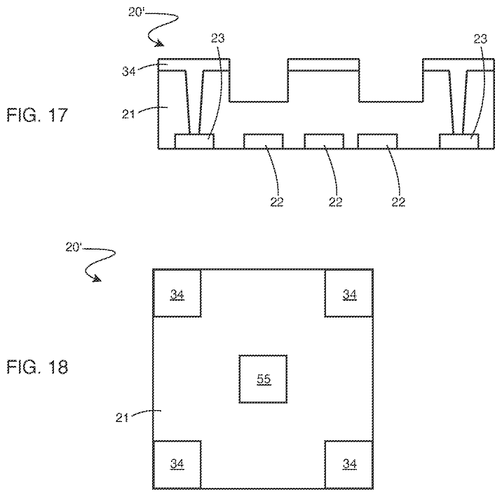

Cavities 35 are then formed in the back face of the wafer 61, thereby defining pillars 52, 53, as shown in FIG. 16. The cavities 35 extend laterally between adjacent ones of the pads 34 and thermal pads 55, and extend partway (but not fully) into the thickness of the wafer 61 such that the portions of wafer material between the surface of the cavities 34 and the pads 22 that contain the active areas remain unharmed. Singulation is then performed via plasma etching or dicing, forming the separate packages 20a′, . . . , 20n′. The packages 20a′, . . . , 20n′ are then removed from the tape 31 and carrier 32, as shown in FIG. 17, ready for integration in a product. A bottom view of the package 20′ may be seen in FIG. 18. Observe that the thermal pad 55 is centrally located on the integrated circuit 21.

It is clear that modifications and variations may be made to what has been described and illustrated herein, without thereby departing from the scope of this disclosure, as defined in the annexed claims.

While the disclosure has been described with respect to a limited number of embodiments, those skilled in the art, having benefit of this disclosure, will appreciate that other embodiments can be envisioned that do not depart from the scope of the disclosure as disclosed herein. Accordingly, the scope of the disclosure shall be limited only by the attached claims.

1. A method of manufacturing, comprising:
providing a wafer having a die area formed therein adjacent a front face thereof, the die area having pads formed thereon;
forming vias in the wafer extending between a back face of the wafer and a back side of some of the pads of the die area;
forming solder pads connected to the vias and forming a thermal pad on the back side of the wafer opposite to the die area;
forming cavities in the back face of the wafer to define pillars extending outwardly from a planar portion of the die area, some of the pillars having the solder pads at a distal end thereof, at least one of the pillars having the thermal pad at a distal end thereof; and
singulating the wafer to form a chip-sized package including an integrated circuit die, the integrated circuit die formed from remains of the die area after singulation.

2. The method of claim 1, wherein forming the vias in the wafer comprises:
forming holes in the wafer extending between the back face of the wafer and the back side of some of the pads of the die area; and
plating the holes to form through silicon vias.

3. The method of claim 1, wherein forming the solder pads and forming the thermal pad on the back face of the wafer opposite to the die area comprises plating the back face of the wafer opposite to the die area and performing etching to form the solder pads and the thermal pad.

4. The method of claim 1, wherein forming the cavities in the back face of the wafer comprises plasma etching the back face of the wafer.

5. The method of claim 1, further comprising attaching the integrated circuit die to a printed circuit board by soldering the solder pads at the distal ends of some of the pillars to pads on a top face of the printed circuit board.

6. The method of claim 1, further comprising prior to forming the vias in the wafer:
providing a secondary integrated circuit having pads on a front face thereof; and
attaching the secondary integrated circuit to the die area by connecting some of the pads of the die area to the pads of the secondary integrated circuit via solder balls.

7. The method of claim 4, further comprising, after attaching the secondary integrated circuit to the die area but prior to forming the vias in the wafer, forming a molding layer over the front face of the wafer and portions of the secondary integrated circuit.

8. The method of claim 1, further comprising placing the wafer with its front face down on a carrier prior to forming the vias.

9. A method of increasing board level reliability of a system including a chip-sized package mounted to a printed circuit board, the method comprising:
forming cavities in a back face of a primary integrated circuit die within the chip-sized package to define pillars extending outwardly from a planar portion of the primary integrated circuit die;
forming pads on distal ends of the pillars; and
soldering those pads to corresponding pads on the printed circuit board.

10. The method of claim 9, further comprising attaching a secondary integrated circuit die to a front face of the primary integrated circuit die by connecting pads on the front face of the primary integrated circuit die to pads of the secondary integrated circuit via solder balls.

11. A system, comprising:
a chip-sized package mounted to a printed circuit board;
wherein the chip-sized package comprises:
a primary integrated circuit die having a back face connected to a printed circuit board;
cavities formed in the back face of the primary integrated circuit die to define pillars extending outwardly from a planar portion of the primary integrated circuit die; and
pads formed on distal ends of the pillars;
wherein the pads on the distal ends of the pillars are connected to corresponding pads on the printed circuit board by surface mount solder.

12. The system of claim 11, wherein the chip-sized package includes a secondary integrated circuit die mounted to a front face of the primary integrated circuit die via solder balls between corresponding pads of the secondary integrated circuit die and the primary integrated circuit die.

13. The system of claim 11, wherein the primary integrated circuit die has through-silicon vias extending from a back face of pads formed in a front face of the primary integrated circuit die to corresponding ones of the pads on the distal end of the pillars.

14. The system of claim 11, wherein a distal end of one of the pillars defined by the cavities has a thermal pad; and wherein the thermal pad is connected to a corresponding pad on the printed circuit board by surface mount solder.

15. The system of claim 11, wherein the primary integrated circuit die has through-silicon vias extending from a back face of pads formed in a front face of the primary integrated circuit die to corresponding ones of the pads on the distal end of the pillars; wherein one of the pillars defined by the cavities has a thermal pad on its distal end, with this pillar lacking a through-silicon via extending therethrough; and wherein the thermal pad is connected to a corresponding pad on the printed circuit board by surface mount solder.

16. A chip-sized package, comprising:
a primary silicon die having a planar portion with an active area formed therein;
at least two pillars extending from the planar portion, wherein one of the pillars is centrally located within the planar portion;
pads located on a front face of the primary silicon die, wherein certain ones of the pads overlie the pillars and other ones of the pads overlie the planar portion;
wherein at least one of the pillars has vias extending therethrough to electrically connect certain ones of the pads on the front face to other pads formed on distal ends of the pillars;
a thermal pad located on a back face of the primary silicon die on the distal end of the centrally located pillar; and
cavities formed at the back face of the primary die, the cavities forming open chambers in combination with a printed circuit board when the primary die is mounted on the printed circuit board.

17. The chip-sized package of claim 16, wherein further comprising solder joints electrically and mechanically connecting the pads on the distal ends of the pillars to pads of the printed circuit board, and wherein the thermal pad is mechanically connected to a corresponding pad on the printed circuit board by a solder joint.

18. The chip-sized package of claim 16, further comprising a secondary silicon die, with solder balls connecting pads of the primary silicon die to pads of the secondary silicon die.

19. The chip-sized package of claim 18, wherein the cavities in combination with the printed circuit board provide flexibility to the primary silicon die, allowing it to flex in response to mechanical stresses and thermal expansion differences between the primary die and the printed circuit board, the flexibility effectively mechanically decoupling a secondary die from said mechanical stresses.
